(19) United States
(12) Patent Application Publication
(10) Pub. No.: US 2011/0032070 A1
(43) Pub. Date: Feb. 10, 2011

(54) WIRELESS SWITCHING AND ENERGY MANAGEMENT

(76) Inventor: Leonard BLEILE, Calgary (CA)

Correspondence Address: SEAN W. GOODWIN, 222 PARKSIDE PLACE, 602-12 AVENUE S.W., CALGARY, AB, T2R 1J3, CA

(21) Appl. No.: 12/854,156

(22) Filed: Aug. 10, 2010

Related U.S. Application Data
(60) Provisional application No. 61/232,600, filed on Aug. 10, 2009.

(51) Int. Cl. G05B 23/02; H01H 47/00; H05K 13/00

(52) U.S. Cl. 340/3.51; 361/160; 29/592.1

(57) ABSTRACT

A wireless switching apparatus is provided for three-way switching at least one energy load with an AC power source. The apparatus comprises a relay controlled by a controller. The controller is also connected to both a toggle and a wireless transceiver. A remote wireless transceiver unit is in communication with the wireless transceiver. The controller operates the relay for making and breaking electrical continuity between the energy load and an AC power source in response to a change in the state of either toggle or wireless signals received from the remote wireless transmitting unit. Control of the energy load using a combined system comprising an energy monitoring device operatively coupled to the apparatus is also provided. Methods are provided for retrofitting conventional receptacles and switches with the wireless switching apparatus.

### FIELD OF THE INVENTION

The invention relates to wireless switching apparatus and methods for installation and use. More particularly, the invention relates to a wireless three-way switching apparatus for remote and local control of at least one energy load. The invention also relates to load monitoring and control using the switching apparatus and an energy monitoring device. One form of energy monitoring device comprises a Hall Effect current sensor.

### BACKGROUND OF THE INVENTION

Common electrical apparatus or appliances, such as a dishwasher, toaster, or lights, are generally energized by means of an AC power source. The appliance has electrical contacts or an electrical switch for connecting and disconnecting the appliance's electrical load from the AC source. The status (on or off) of the electrical appliance can be controlled by the electrical switch as long as the appliance's local on/off switch remains closed (on) to electrically connect the load and the relay.

The status of such electrical appliances can also be controlled remotely as long as the appliance's local on/off switch remains closed (on). In some instances, the AC receptacle to which the electrical appliance is plugged is provided with an intermediate device having a receiver connected to a relay. The receiver receives signals from a remote control unit and, depending upon the signals received, the receiver opens or closes the relay for connecting and disconnecting the electrical appliance from the AC source thereby changing the status of the electrical appliance. However, the system is inoperable if a user wishes to locally control the electrical appliance without using the remote control unit. For example, if a user manually turns off a lamp by opening the electrical connection at the lamp, the receiver and relay are powerless to close those contacts. There is a need to provide a more convenient system for providing remote and local control.

It is known to measure the power consumed by the electrical appliance using an energy monitoring device. The electrical appliance is plugged into the energy monitoring device which in turn is typically plugged into an AC receptacle. The energy monitoring device can display the power consumed by the electrical appliance by measuring electrical values such as current, voltage and power. An example of an energy monitoring device is “Kill A Watt™ marketed by P3 International, of New York, N.Y.

To the best of Applicant's knowledge, most energy monitoring devices use current transformers for measuring the current flowing through the AC receptacle. Current transformers are bulky and occupy more board space when mounted on a printed circuit board (PCB). Alternate devices include Hall Effect current sensors, however, to date it is believed these devices are limited to low power applications.

### SUMMARY OF THE INVENTION

The present invention provides improvements to management and wireless control of energy loads such as electrical appliances or apparatus. Generally, wireless apparatus is provided including implementation of three-way control, in-wall or plug-in receptacle devices, retrofit capability and integration of energy management. With energy management, electrical loads can be monitored, controlled and managed including for problem detection.

In one embodiment, three-way switching apparatus is provided which enables a user to change a status of an electrical appliance either locally or remotely without disabling the other operation. Existing hard-wired “local operation-only” switches and receptacles can be retrofit to enable both local and wireless remote operations. Further existing hard-wired switches can be easily replaced with apparatus of the present invention by the minimally skilled, enabling a greater opportunity and control of the original load or alternate loads with the wireless apparatus.

Embodiments of the present invention also provide control of an electrical appliance using a combined system comprising an energy monitoring device operatively coupled to the wireless switching apparatus. Control includes management of loads based on one or more external variables including time of day, duration, temperature and characteristics of the load itself.

Further, the energy monitoring device can be incorporated in a low cost and compact apparatus using particular implementation of a Hall Effect current sensor. In one embodiment, the Hall Effect current sensor is mounted on one side of a printed circuit board (PCB) substrate. Avoiding load restrictions of conventional Hall Effect sensors, a copper track or trace for carrying the current to be measured is located, without size and current restriction, on the other side of a magnetically transparent PCB substrate.

In one aspect of the present invention a wireless apparatus for switching at least one energy load with an AC power source comprises a load-interface device having a relay between the at least one energy load and the AC power source; a controller operatively connected to the relay; a toggle and a wireless transceiver connected to the controller; and a remote wireless transceiver unit in communication with the wireless transceiver. The controller operates the relay for changing the state of the electrical continuity between the at least one energy load and the AC power source in response to a change in state of the toggle regardless of a state signaled through wireless signals received from the remote wireless transmitting unit, and in response to a change in the state signaled through the wireless signals received by the transceiver from the wireless transceiver unit regardless of the state of the toggle.

In another aspect of the present invention a combined system for controlling at least one energy load comprises an energy monitoring device operatively coupled to the wireless switching apparatus.

In another aspect of the present invention, a method for controlling at least one energy load is provided comprising maintaining a log of power consumed by the at least one energy load over a set period of time to arrive at an average power consumed by the at least one energy load. The power consumed by the at least one energy load is measured at a given instant to arrive at an instant power and is compared with the average power. One determines that the at least one energy load is outside operating limits when the instant power exceeds the average power by a predetermined tolerance.

In another aspect of the present invention, a method for retrofitting conventional system with wireless system comprises replacing a conventional receptacle for receiving a plug of the at least one energy load or an electrical switch controlling the at least one energy load with the controlled receptacle. In another aspect, the method for retrofitting conventional system with wireless system comprises replacing the conventional receptacle for receiving a plug of the at least one energy load with the controlled receptacle; and replacing the conventional electrical switch controlling the at least one energy load with an electrical outlet adapted to receive the remote wireless transceiver unit, the remote wireless transceiver unit comprising an interface for activating the transceiver unit.

### BRIEF DESCRIPTION OF THE DRAWINGS

FIG. 1 is a schematic illustration of an electrical appliance connected to a conventional AC receptacle and controlled by a switch according to the prior art;

FIG. 2 is a schematic illustration of an electrical appliance connected to a conventional AC receptacle and controlled by a remote control unit according to the prior art;

FIG. 3 is a block diagram of a wireless three-way switching apparatus according to an embodiment of the invention;

FIG. 4 is a schematic illustration of an electrical device controlled by the switching apparatus of FIG. 3;

FIG. 5 is a block diagram of the switching apparatus of FIG. 3 operatively coupled to an energy monitoring device;

FIG. 5A is a block diagram of the energy monitoring device of FIG. 5 illustrating the various components thereof;

FIG. 5B is a schematic illustration of a controlled receptacle housing the switching apparatus of FIG. 3 and the energy monitoring device of FIG. 5;

FIGS. 6, 7, 8 and 9 are block diagrams of various implementations of the energy monitoring device of FIG. 5;

FIG. 10 is a flowchart representing the working of the energy monitoring device of FIG. 5 with regard to how current and voltage sensed by the current measuring unit is stored and transmitted;

FIG. 11 is a representation of the payload structure carried from the current measuring unit to the operating unit of the energy monitoring device; and

FIG. 12 is a representation of the payload structure carried from the operating unit to the current measuring unit of the energy monitoring device;

FIGS. 13A, 13B, 13C, 13D and 13E are schematic illustrations of various ways of installing the switching apparatus of FIG. 3;

FIG. 14 is a schematic illustration of various loads being controlled by the switching apparatus of FIG. 3; and

FIG. 15 is a side view of a PCB of the energy monitoring device of FIG. 5 with a Hall Effect current sensor mounted on the PCB according to one embodiment of the invention.

### DETAILED DESCRIPTION OF THE PREFERRED EMBODIMENTS

A first aspect of the invention provides local and remote control (on and off) of at least one energy load using a wireless three-way switching apparatus. As used herein, the term “energy load” generally includes but is not limited to, home appliances and industrial apparatus. Examples of home appliances include lamps, kettles, toasters, dishwashers and car block heaters.

The invention also provides control of at least one energy load using a combined system comprising the switching apparatus interfaced with an energy monitoring device. In addition to monitoring functions, the combined system automatically turns on and off the energy load on the basis of a predetermined set of variables such as energy consumed by the energy load, changes in the energy consumption, energy usage patterns, cost of energy, time of day, temperature conditions around the energy load, or combinations thereof.

Embodiments of the invention are explained herein in the context of control of a single energy load such as a lamp or a car block heater or multiple energy loads.

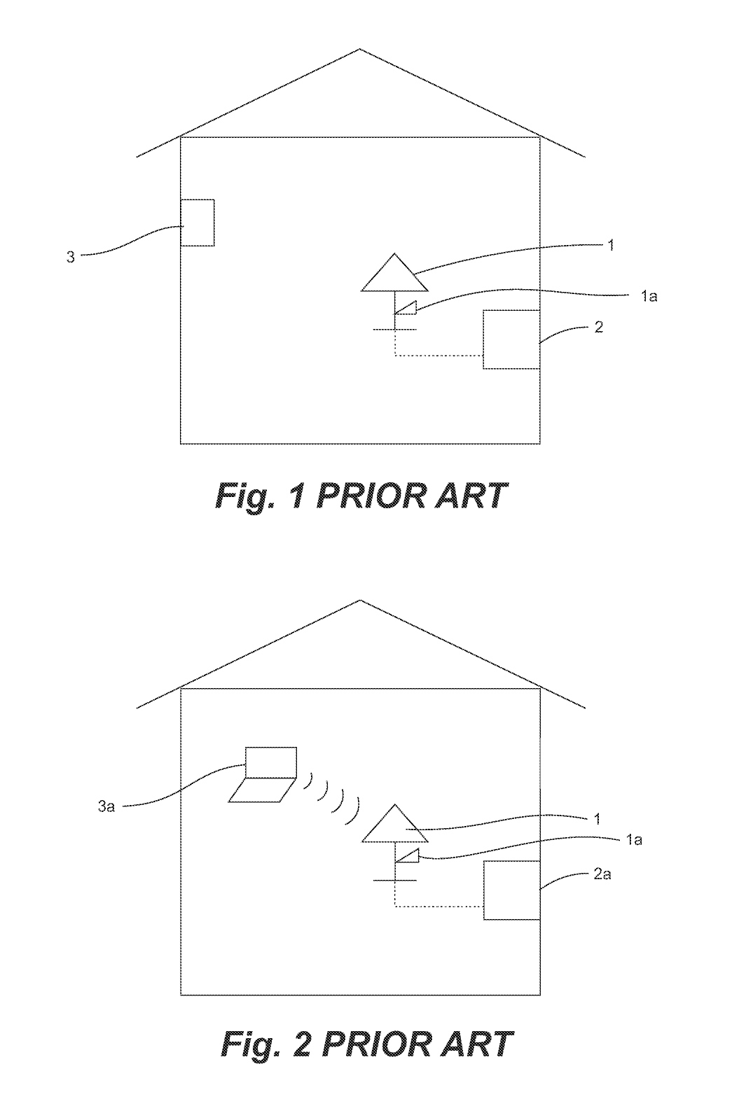

With reference to FIG. 1, it is already known that an energy load such as a lamp 1 is connected to a conventional AC receptacle 2 and controlled locally by an electrical switch 3 according to the prior art. The lamp 1 has a local switch 1a which is set in an “on” position. Further, with reference to FIG. 2, lamp 1 can be connected to a conventional AC receptacle 2a and controlled by a remote control unit 3a according to the prior art. The AC receptacle 2a houses a receiver and a relay (both not shown). The local switch 1a of the lamp 1 is set in an “on” position. With the lamp 1 hard-wired in an “on” state, the user can activate the remote control unit 3a for turning on and off the lamp 1.

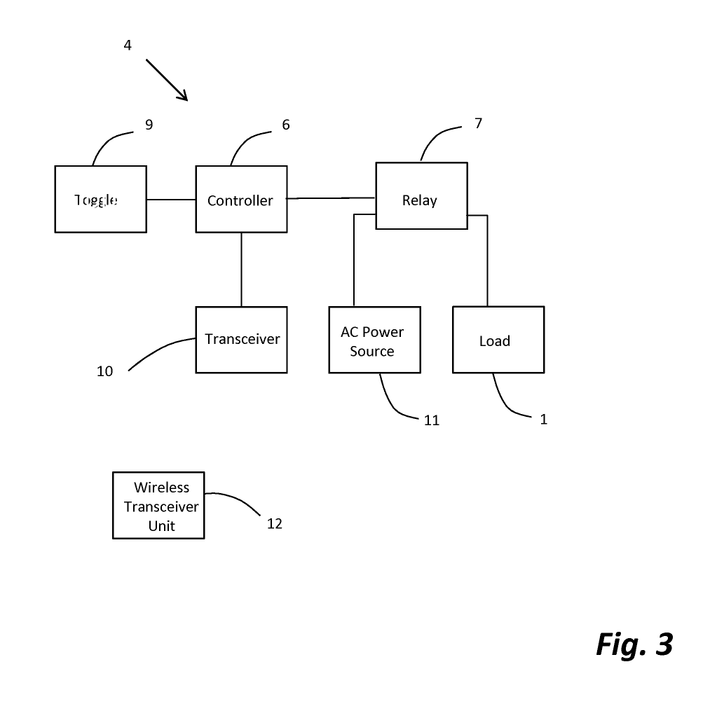

Turning to embodiments on the present invention, as shown in FIGS. 3, 4, and 5B both remote and local control of the lamp 1 is enabled using a wireless three-way switching apparatus of the invention. The lamp 1 itself is configured to be “on” such as hard-wired in an “on” state. The “on” state includes the case where the local lamp switch 1a is set in an “on” position. A wireless three-way switching apparatus 4 is provided which comprises a relay 7 connecting the lamp 1 to an AC power source 11. The relay is controlled by a controller 6 connected to the relay 7. The controller 6 is further connected to a user-operable toggle 9 and a wireless transceiver 10. The toggle 9 can be any electrical contact such as a pushbutton switch, a paddle switch, or a rocker switch.

The switching apparatus 4 further comprises a remote wireless transceiver unit 12 in communication with the wireless transceiver 10. The remote wireless transceiver unit 12 can be a mobile wireless device such as a laptop, a personal digital assistant (PDA), or a cell phone; or a wall mounted wireless device; or a personal computer (PC). The wireless transceiver 10 receives wireless signals which include instructions to change the state of the relay 7.

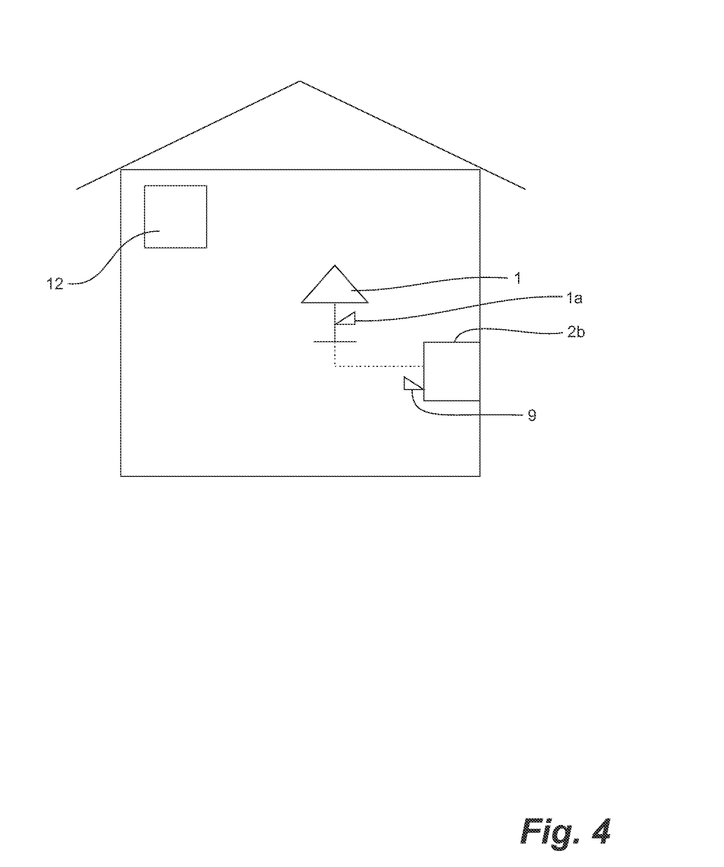

As shown in FIGS. 4, 5B and 13A, and according to one embodiment of the invention, the wireless switching apparatus 4 is installed by replacing a conventional receptacle 2, which normally receives a plug 1b of the lamp 1, with a load-interface device or controlled receptacle 2b comprising the relay 7, the controller 6, the toggle 9 and the transceiver 10. The toggle 9 is located at the controlled receptacle 2b. The lamp 1 is now plugged into the controlled receptacle 2b.

The switching apparatus 4 can be used to change the status of the lamp 1 locally by a user when the local switch 1a of the lamp 1 is left in an “on’ position. This is done by the user changing the position of the toggle 9 at the controlled AC receptacle 2b into which the lamp 1 is plugged in. As a result of switch 1a being left on, the load or bulb of the lamp 1 is already electrically connected to the lamp's plug.

A change in position of the toggle 9 or a wireless signal from the wireless transceiver unit 12 is detected by the controller 6 which in turn causes the relay 7 to move to its opposing state thereby making or breaking the electrical continuity between the lamp 1 and the AC power source 11. As is known with conventional three-way arrangements, changing the state of the relay changes the state of the lamp, turning it on, if it was off, and turning it off, if it was on. The status of the lamp 1 can be changed remotely regardless of the position of the toggle 9. This can be done by a user activating an application on the wireless transceiver unit 12. The wireless signals sent by unit 12 are received by the transceiver 10. The controller 6 in turn causes the relay 7 to move to its opposing state thereby making or breaking the electrical continuity between the lamp 1 and the AC power source 11. The controller 6 can be connected to the relay 7 through a relay driver such as a transistor driven opto coupler.

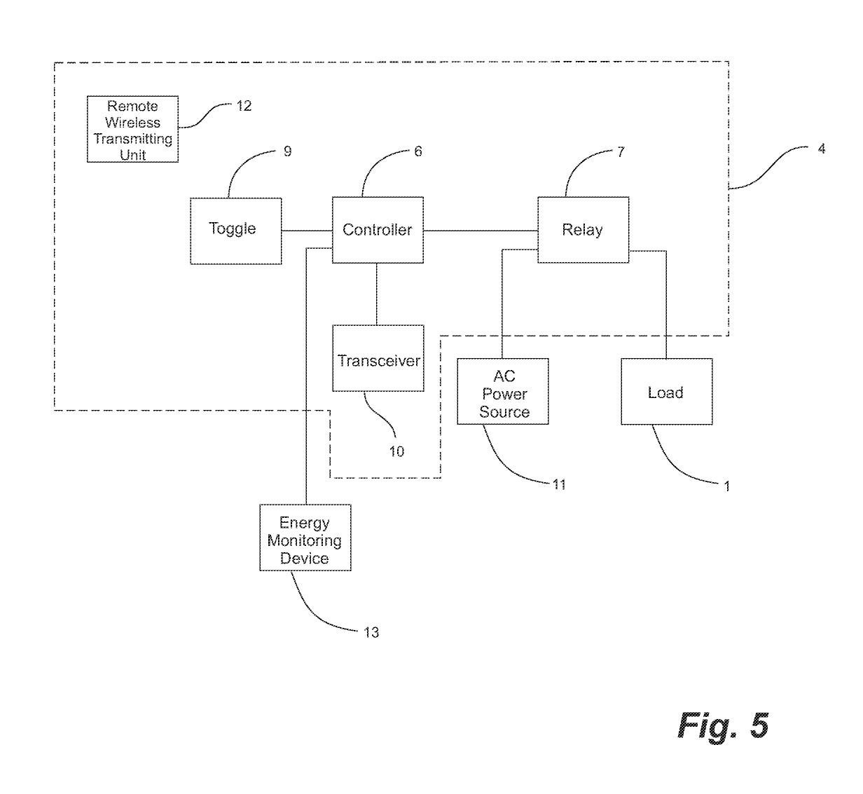

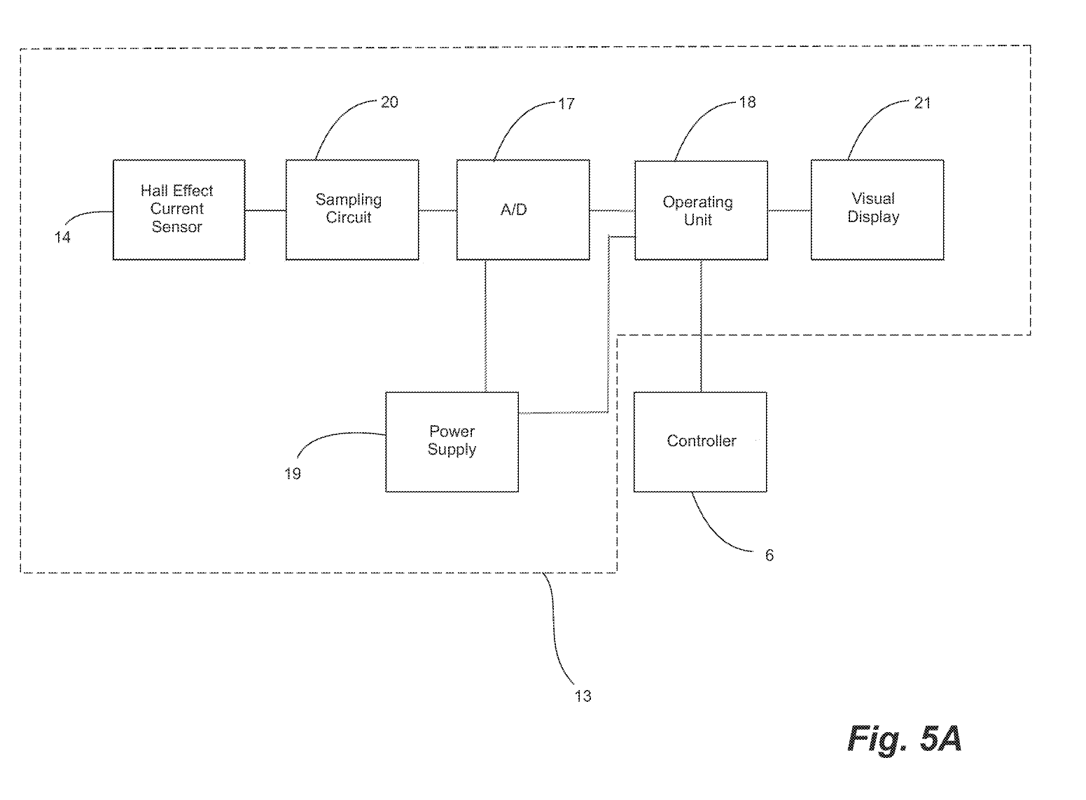

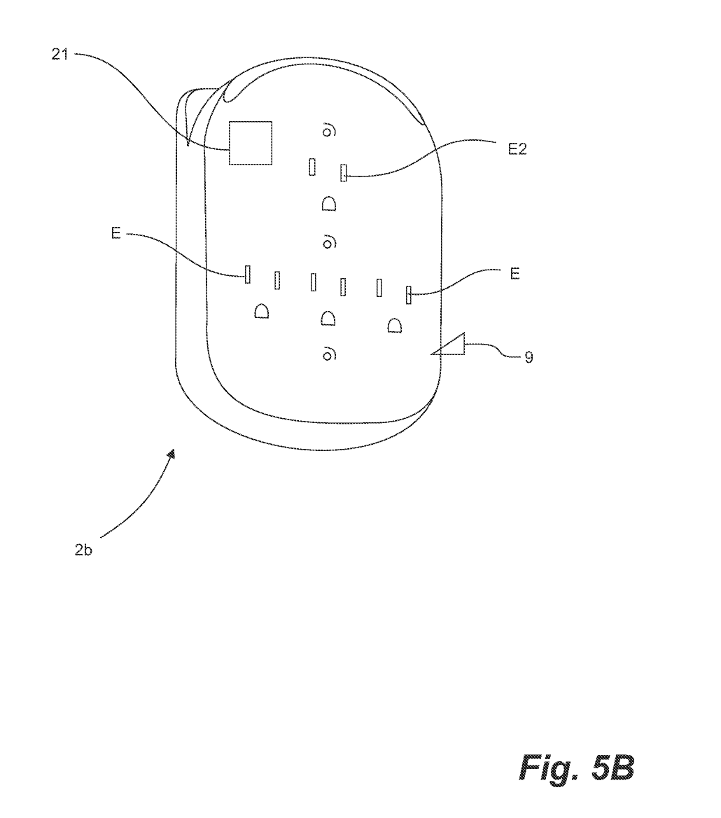

In another aspect of the invention and as illustrated in FIG. 5, the switching apparatus 4 is interfaced or operatively connected or coupled to an energy monitoring device 13. In one embodiment the energy monitoring device 13 is used for automatically turning off and on the energy load based on one or more predetermined set of variables including time of day, duration, temperature, cost of energy associated with power consumption, characteristics of the load 1 and combinations thereof. This operation does not require the intervention of a user.

The energy monitoring device 13 measures electrical values, such as power consumed, at the controlled AC receptacle 2b to which the lamp 1 is connected. The energy monitoring device 13 is also adapted to communicate with the controller 6 to automatically operate the relay 7 for turning on and off the lamp 1 on the basis of the predetermined set of variables. The predetermined set of variables is set by the user. When a select one or more of the predetermined conditions set in the energy monitoring device 13 are satisfied, the energy monitoring device 13 communicates with the controller 6, which in turn moves the relay 7 to its opposing state thereby changing the state of the lamp 1.

The energy monitoring device 13 is also associated with a visual display 21 which can display the electrical values or any of the predetermined set of variables.

The configuration of the energy monitoring device 13 and the interaction of the energy monitoring device 13 with the switching apparatus 4 are explained below with reference to the drawings and specific examples.

In one example and as illustrated in FIG. 5B, the various components of the energy monitoring device 13 are housed or incorporated in the controlled AC receptacle 2b containing the various components of the switching apparatus 4 except the remote wireless transceiver unit 12. The visual display 21 can located on the controlled receptacle 2b or can be located at a remote location. The lamp 1 is plugged into an electrical outlet E provided in the controlled AC receptacle 2b.

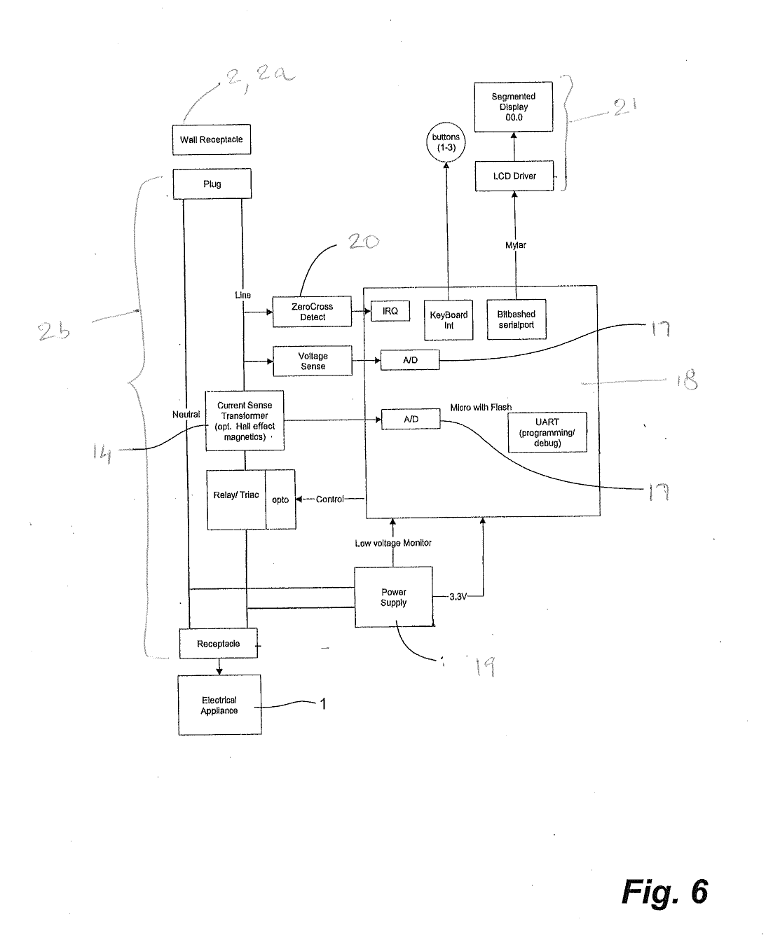

As illustrated in FIGS. 5A and 6, the energy monitoring device 13 comprises an analog to digital converter (A/D converter) 17 connected to a microcontroller or operating unit 18 and a current measuring unit and/or a power measuring unit. In one embodiment of the invention, the current measuring unit includes a Hall Effect current sensor 14 for measuring the current flowing through the AC receptacle 2b to which the lamp 1 is connected. The current measuring unit could also be a current transformer, connected in series with the AC power source 11. The operating unit 18 and the A/D converter 17 are powered by a power supply 19. The operating unit 18 is adapted to communicate with the controller 6 of the switching unit 4. In one embodiment of the invention, the Hall Effect current sensor 14 is connected to the A/D converter 17 through a sampling circuit 20. The sampling circuit may be a zero crossing circuit. The operating unit 18 of the energy monitoring device 13 can also be programmed to calculate the real and apparent power from the current sensed by the Hall Effect current sensor 14.

The visual display 21 associated with the energy monitoring device 13 may be a LCD display or an array of LED's. The visual display 21 is controlled by the operating unit 18.

The current sensed by the Hall Effect current sensor 14 is sampled and fed to the analog to digital converter 17 which in turn converts the sampled analog signals to digital signals. The digital signals correspond to the sensed current. The digital signals are received by the operating unit 18 which processes the signals and generates output signals which are fed to the controller 6 and the visual display 21. The nature of the output signals are as follows: signals to turn on or off the lamp 1. This is based on the value of the sensed current and whether the predetermined variables set by the user have been met with; energy consumed by the lamp 1. This is displayed on the visual display 21; cost associated with the energy consumed by the lamp 1. These output signals are displayed on the visual display 21. Depending upon the signals received by the controller 6, the relay 7 is opened or closed for changing the status of the lamp 1.

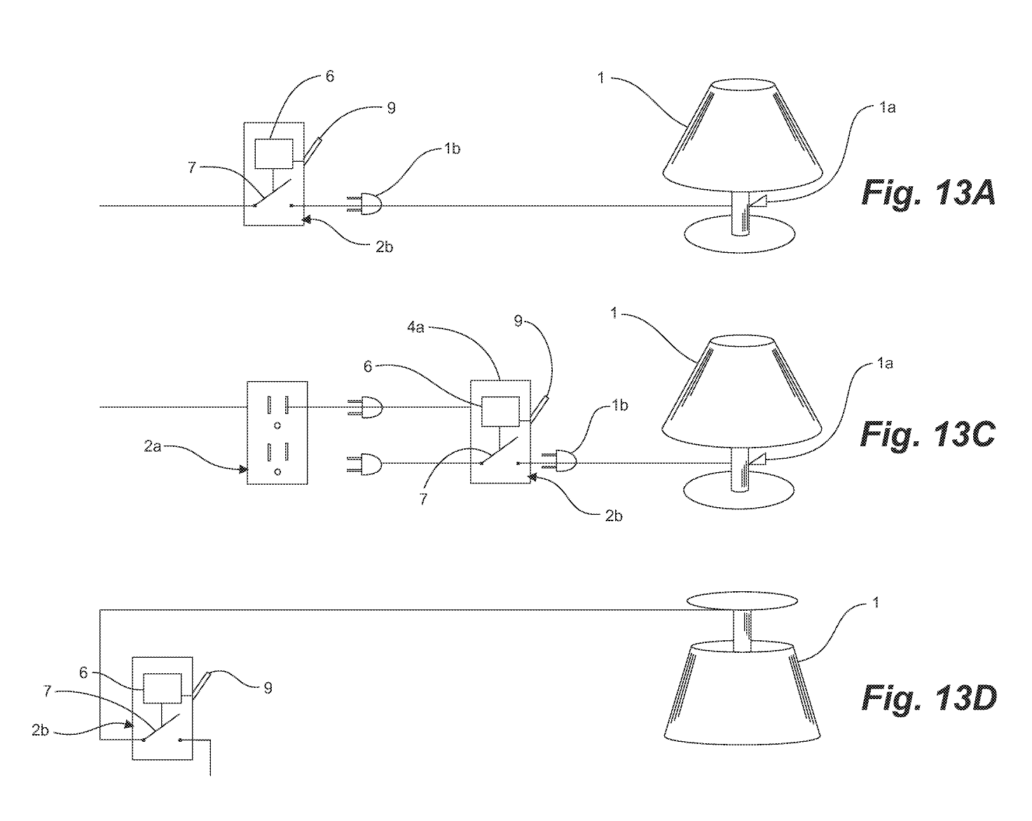

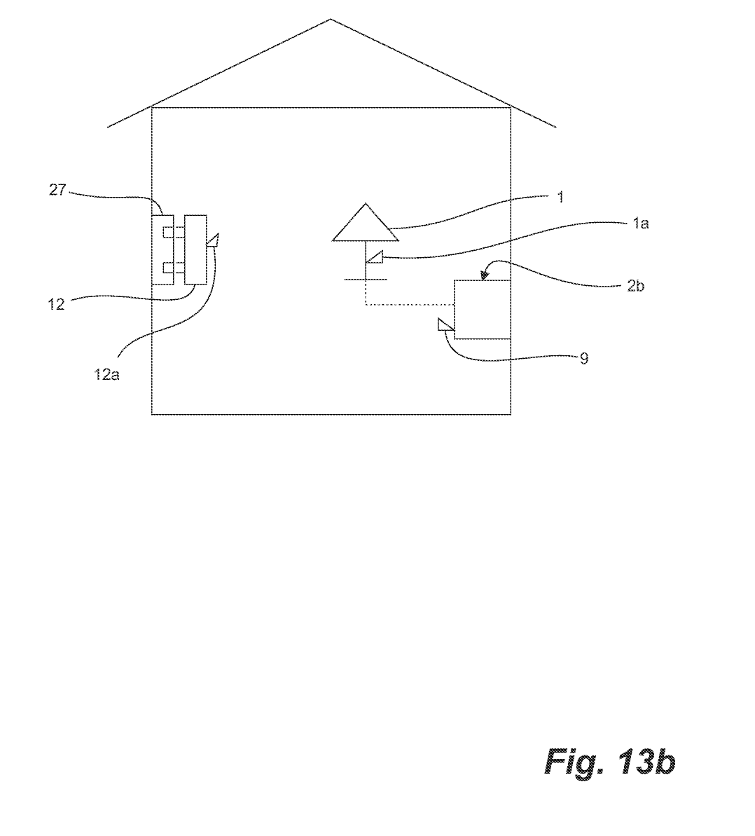

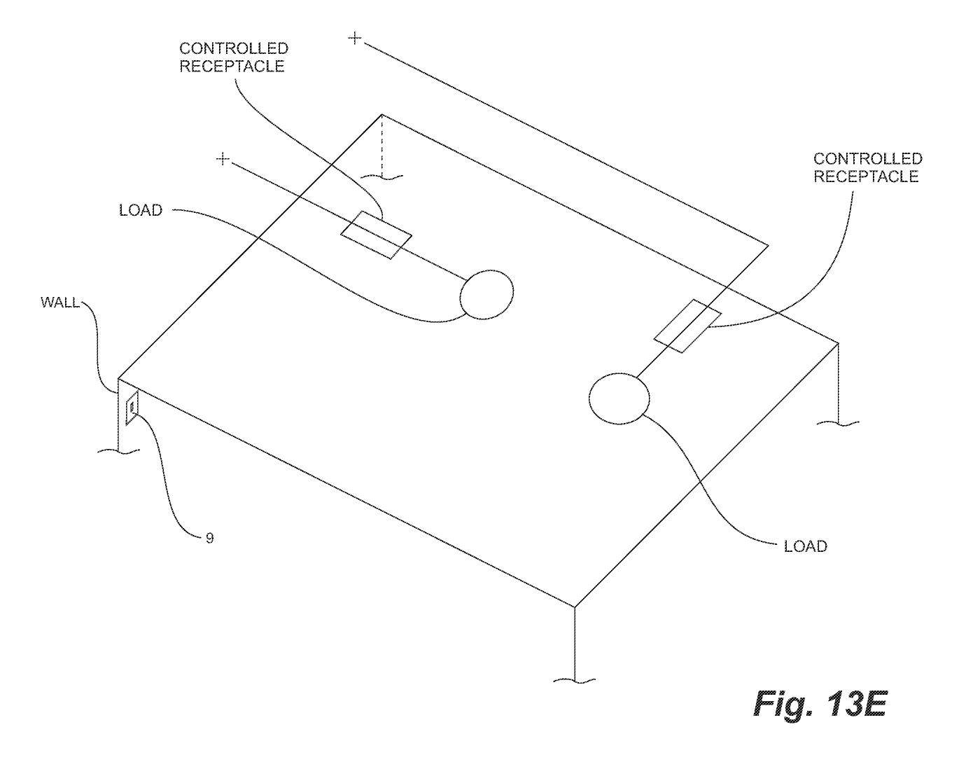

In further examples, the interaction of the energy monitoring device 13 and the switching apparatus 4 is described for changing the state of a single energy load on the basis of a predetermined set of variables. The energy loads are described in the context of a lamp 1, a car block heater and an electrical appliance. As shown in FIG. 13A, the energy monitoring device 13 and the switching apparatus are housed in the controlled receptacle 2b. The energy load is plugged into the controlled receptacle 2b. The energy monitoring device 13 measures and displays power consumed at the AC receptacle 2b to which the lamp 1 is connected. The energy monitoring device 13 is adapted to communicate with the controller 6 to automatically turn off the lamp 1 when power consumed by the lamp 1 exceeds a predetermined limit.

In this example, as the energy monitoring device 13 measures power, it allows a user to identify instances where power is being wasted, such as when a controlled receptacle draws current, even when a load plugged into the receptacle is not in use. This is usually the case with loads such as linear power supplies or appliances such as televisions that constantly use power even when the load is in an idle or off state.

In another example, as the energy monitoring device 13 measures power, it allows a user to verify whether an energy efficient load actually uses as little power as advertised. If the electrical appliance was advertised as consuming 1100 watts and in actual use consumes 1500 watts, the user will be able to identify this difference using the energy monitoring device 13 and take corrective actions based on this measurement.

In another example, the operating unit 18 of the energy monitoring device 13 can be programmed to calculate the cost associated with the power consumed at the receptacle 2b to which the lamp 1 is connected. The operating unit 18 calculates the cost based on the cost of power from the local energy provider which is stored therein. The cost of power may be updated periodically. The visual display 21 displays the cost associated with the usage of the lamp 1 plugged into the AC receptacle 2b and also the power consumed by the lamp 1 during its operation. The energy monitoring device 13 can also be adapted to communicate with the controller 6 to automatically turn off the lamp 1 when the cost associated with the power consumed by the lamp 1 exceeds a predetermined cost limit.

Further, in another example, as the energy monitoring device 13 measures power and costs associated with the power consumption, it allows a user to see the difference in cost when a load is run at peak time or non-peak time and allows a user to schedule operation of the load when the energy cost is low. If the cost of energy is high during the day time, a user could set the energy monitoring device 13 to turn on an electrical appliance during the non-peak time thereby saving money.

In another example, the energy monitoring device 13 can be used to detect faults in an energy load. Each energy load that is being monitored by the energy monitoring device 13 will exhibit power consumption characteristics. As the energy load ages, this consumption could change as problems occur, or due to general wear and tear of the components of the load.

This is useful for large energy loads including industrial apparatus. The energy monitoring device 13 is adapted to look for these patterns and alert users before a problem becomes catastrophic. For example if an excess current is detected in an energy load it will be flagged for repair or shut down. This is very useful for large energy loads that cost more to operate when not in an optimal state of repair. A simple maintenance check up after being flagged could bring the energy load back into specification and cause it to run more efficiently, saving more power. There is no need to wait for a hard failure when problems could be preventatively detected and addressed. System stress and overloading can be detected at early stages.

The energy monitoring device 13 identifies whether the electrical appliance is outside operating limits and needs repair by: maintaining a log of power consumed by the electrical appliance over a set period of time to arrive at an average power consumed by the electrical appliance; measuring the power consumed by the electrical appliance at a given instant to arrive at an instant power; comparing the instant power with the average power; and determining that the electrical appliance needs repair when the instant power exceeds the average power by a predetermined tolerance.

In another example, energy loads such as a car block heater are typically plugged in and draw power well in advance of being used. This is a waste of energy and money. Using the energy monitoring device 13, a user can set a temperature range and/or other predetermined variables to turn on the car block heater at a more opportune time. A user may set the energy monitoring device 13 to enable the car block heater such as when the temperature drops below a set value or −10 degrees Celsius and several hours before the car is needed, such as between 3:00-5:00 am before going to work. The energy monitoring device 13 is adapted to communicate with the controller 6 to automatically turn on and off the car block heater when both the set conditions are satisfied.

### Installation

According to one embodiment of the invention and as illustrated in FIGS. 5B and 13A, the wireless switching apparatus 4 can retrofit or installed by replacing the conventional receptacle 2,2a with a controlled receptacle 2b. In this embodiment, the remote wireless transmitting unit 12 is a mobile wireless device such as a cell phone or a laptop or a PDA. The various components of the energy monitoring device 13 are incorporated in the controlled AC receptacle 2b.

According to another embodiment of the invention, as illustrated in FIGS. 5B and 13B, the wireless three-way switching apparatus 4 is installed by replacing the conventional receptacle 2, 2a with a controlled receptacle 2b. The conventional electrical switch 3 controlling the energy load is replaced with an electrical outlet 27 adapted to receive the remote wireless transmitting unit 12. The wireless transmitting unit 12 is provided with an interface 12a for activating it. Existing hard-wired electrical switches and receptacles can be retrofit to enable both local and wireless remote operations. The various components of the energy monitoring device 13 are incorporated in the controlled AC receptacle 2b.

The switching apparatus 4 can be installed by an ordinary home owner as it does involve re-routing of the wiring.

According to another embodiment of the invention and as illustrated in FIG. 13C, the wireless three-way switching apparatus 4 is installed by locating the relay 7, the controller 6 and the transceiver 10 in a housing 4a. The housing 4a is adapted to plug into the conventional AC receptacle 2 or 2a. The toggle portion 9 is provided on the housing. The housing 4a is further provided with an electrical outlet for receiving the plug 1b of an energy load such as the lamp 1. The various components of the energy monitoring device 13 are incorporated in the controlled AC receptacle 2b.

According to another embodiment of the invention as illustrated in FIGS. 5B and 13D, the wireless three-way switching apparatus 4 is installed by replacing the electrical switch 3 of a hardwired load 1, such as a ceiling lamp, with a controlled receptacle 2b comprising the relay 7, the controller 6, the toggle portion 9 and the transceiver 10.

According to another embodiment of the invention as illustrated in FIGS. 5B and 13E, an inline wireless switching apparatus 4 is installed to an energy load such as a ceiling lamp 1. The switching apparatus 4 comprises the controller 6 and the relay. The toggle 9 is mounted remotely, such as on a wall in the vicinity. The toggle 9 is part of another wireless transceiver 12 or controlled receptacle 2b. The switching apparatus can be addressed to control this load 1 or some other same-addressed load 1.

Having reference to FIG. 5B, and in instances where the supply of electricity is critical and cannot be subject to component failure or interruption, such as in the case of medical equipment, the controlled AC receptacle 2b can be provided with a bypass outlet E2. An energy load plugged into the bypass outlet E2 is connected to the AC power source 11 without an intermediate the switching apparatus 4.

### Energy Monitoring

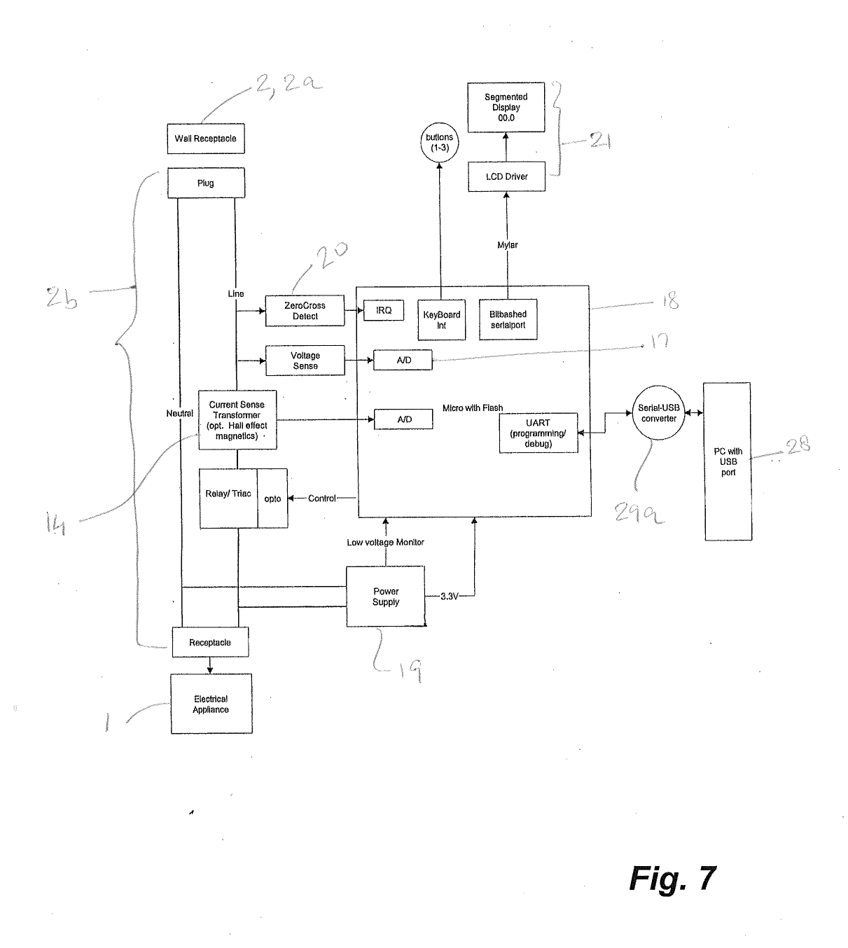

FIGS. 7 to 9 illustrate various ways of implementing the energy monitoring device 13.

Having reference to FIG. 7, information stored in the energy monitoring device 13 can be transferred to a personal computer 28 using a universal serial bus (USB) converter 29a.

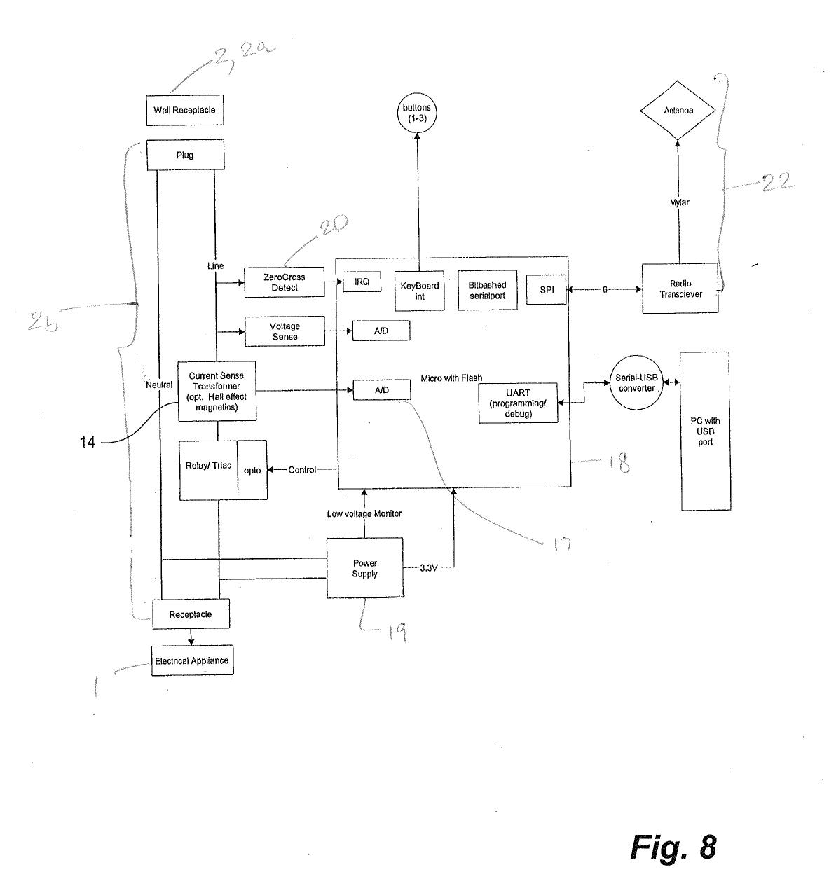

Having reference to FIG. 8, the information stored in the energy monitoring device 13 is transmitted wirelessly to an external memory (not shown) through a radio transceiver 22. The energy monitoring device 13 is adapted to store the information for a limited period of time before the same is transmitted. The external memory may form a part of a Personal Computer (PC).

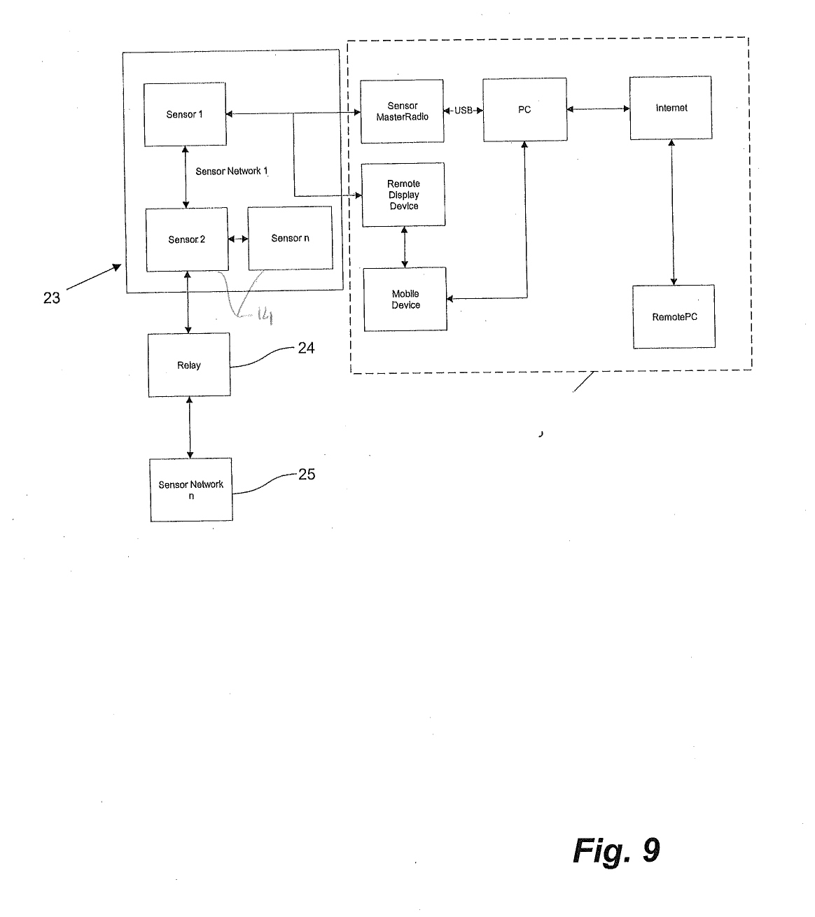

Having reference to FIG. 9, the operating unit 18 of the energy monitoring device 13 is adapted to receive data wirelessly from a network 23 of Hall Effect sensors sensing currents consumed at other AC receptacles (different from the AC receptacle 2b comprising the various components of the energy monitoring device). The operating unit 18 is also adapted to receive data from a network 25 of Hall Effect current sensors which are not in the wireless range through a relay or wireless extender 24. This allows the network 25 of Hall Effect current sensors which are physically distant from the operating unit 18 to be placed in wireless communication with the operating unit 18. The network 23 and 25 of Hall Effect current sensors are associated with transceivers which transmit the sensed current data to the operating unit 18. The data transmitted by the network 23 and 25 of Hall Effect current sensors may be associated with the time that they were sensed so that they could be properly displayed on the visual display 21 of the energy monitoring device 13 even if there was a delay in receiving the current data by the operating unit 18 due to certain technical disruptions. This also allows the operating unit 18 to be powered down or taken out of range for long periods of time without causing a loss of data. In this way the operating unit 18 does not need to be constantly on, using power when not necessary. It also allows Hall Effect current sensors to be placed into an environment and left to gather data without involvement of any operating unit. Later the Hall Effect current sensors can be removed and the data stored in them can be transmitted to an operating unit for analysis.

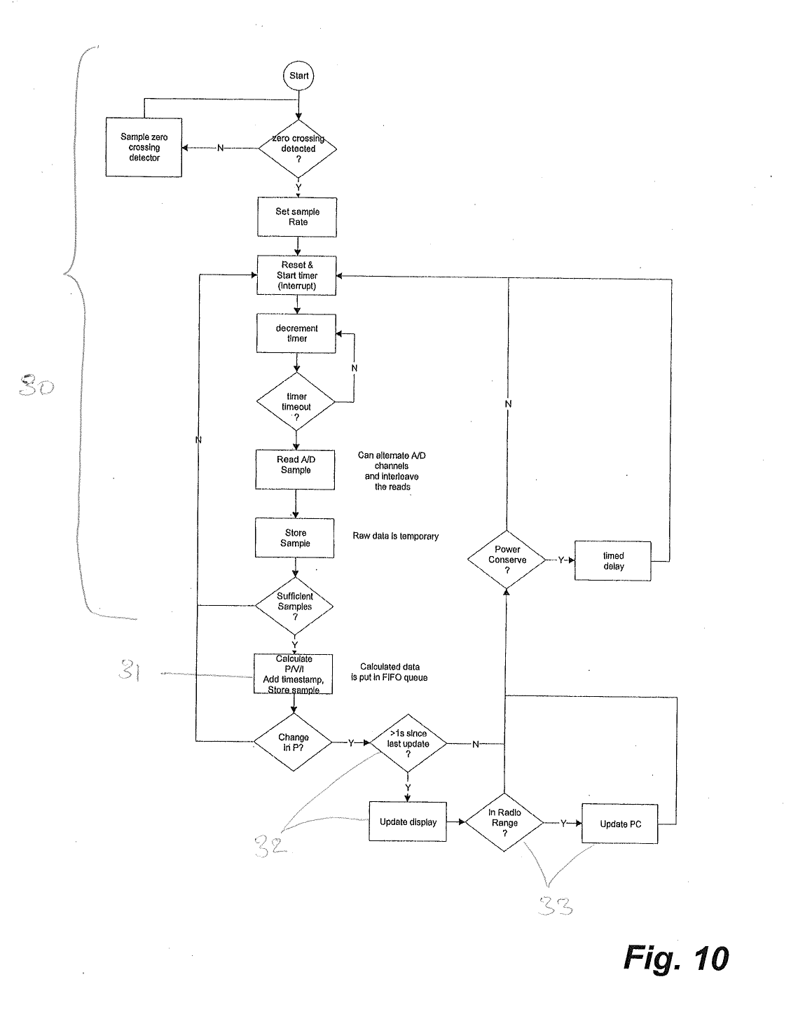

FIG. 10 is a flowchart representing the working of the energy monitoring device 13. The current sensed by the Hall Effect current sensor 14 is sampled and converted into digital signals (blocks 30). The sensed current is used to generate various electrical values such as power and voltage and such values are associated with time stamps (block 31). The generated values are displayed on the visual display 21 (blocks 32). The generated values can be transferred to an external memory (blocks 33) when in transmission range.

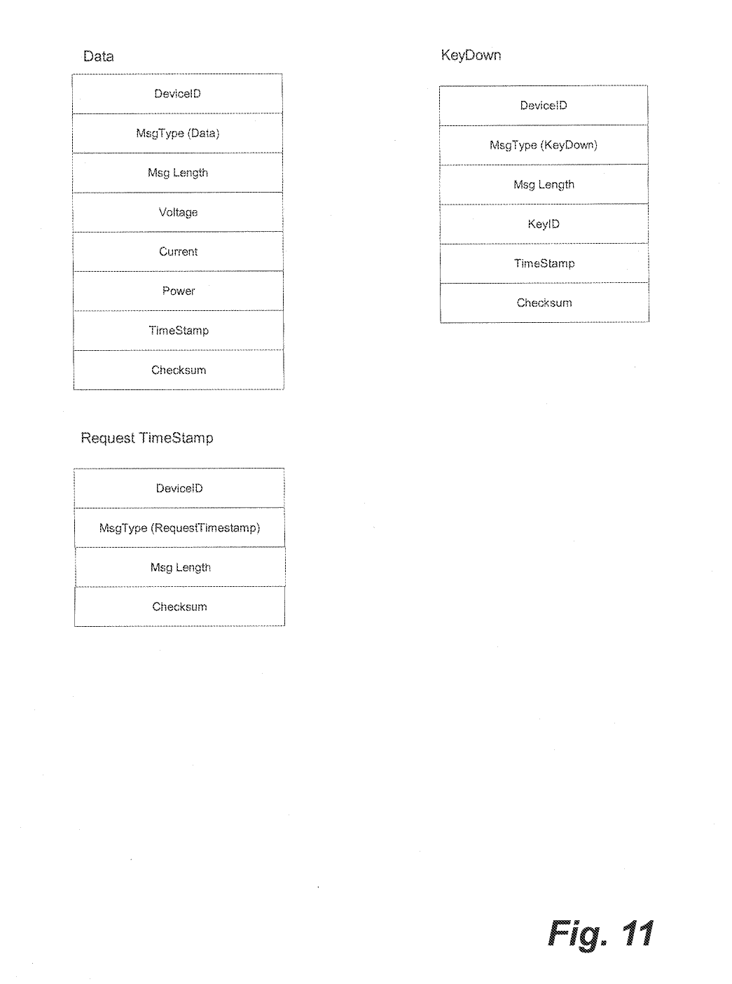

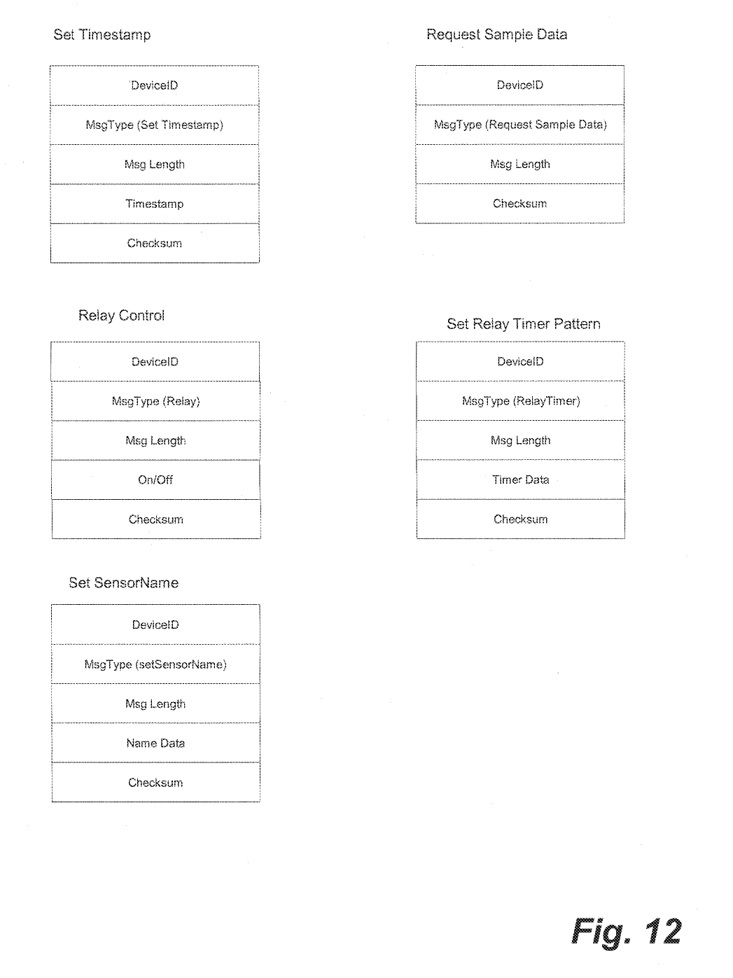

FIGS. 11 and 12 are representations of the payload structure carried between the Hall Effect sensor(s) 14 and the operating unit 18 of the energy monitoring device 13. The payload structure includes data such as details of the controlled receptacle and load, power consumed at the controlled receptacle, cost associated with the power consumption, time at which a certain amount of power was consumed.

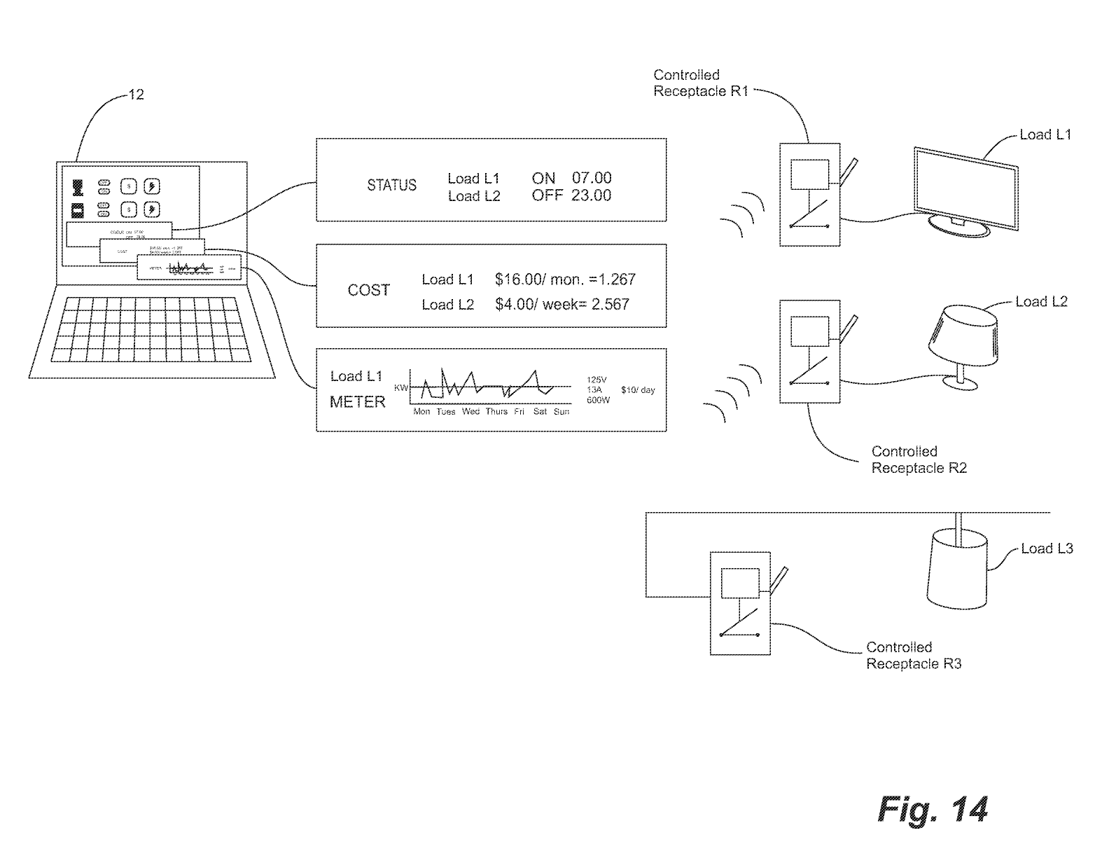

FIG. 14 is a schematic illustration of multiple loads being controlled by the switching apparatus of the invention. The various loads are marked L1, L2 and L3. The controlled receptacles housing the switching apparatus of the invention are marked R1, R2 and R3. Each controlled receptacle incorporates an energy monitoring device. A form of remote wireless transceiver unit 12 is illustrated which has a visual display such as a laptop or a cell phone or a PDA. The remote wireless transceiver unit 12 is adapted to communicate with the wireless transceivers (not shown) housed in the controlled receptacles R1, R2 and R3. The remote wireless transceiver unit 12 is also adapted to communicate with the energy monitoring device measuring the voltage and the current at the controlled receptacles R1, R2 and R3. The power consumed at each of the controlled receptacles R1, R2 and R3 and the cost associated with such power consumption is displayed at the remote wireless transceiver unit 12. A user can change the status of the loads by activating an application stored in the remote wireless transceiver unit 12. A user can also change the status of the loads by activating an application stored in the remote wireless transceiver unit 12 which is also dependant on various predetermined variables set in the remote wireless transceiver unit 12 by the user. The various predetermined variables are in turn dependant on at least the power consumed at each of the controlled receptacles R1, R2 and R3 and the cost associated with such power consumption.

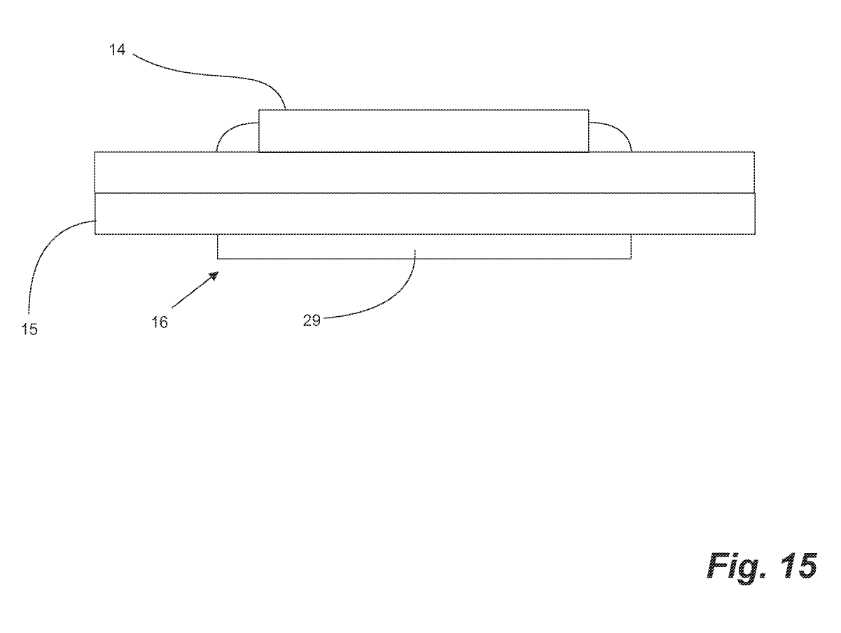

In an embodiment of the invention as illustrated in FIG. 15, the Hall Effect current sensor 14 is an integrated circuit and is mounted on one side of a substrate 15 of a printed circuit board (PCB) 16. At least one copper track 29, carrying the current to be measured, is located on an other side of the substrate 15 and is operatively positioned with respect to the Hall Effect current sensor 14. The dimensions of the copper tracks of the PCB are related to the amount of current the track must carry. The current flowing through most energy loads described herein can range from 15 A to 20 A. For most energy loads described herein, the voltage and frequency of the AC power source 11 can range from 90V-240V and 47 Hz-63 Hz, respectively. In a conventional PCB, if a copper track carrying the 15 A current were to be mounted on the same side of the substrate on which the current measuring component (Hall Effect current sensor or current transformer) is mounted, and located between the pins of the current measuring component, the copper track would be too wide and have to be accommodated in a deep trench in the substrate. Etching deep trenches in the substrate results in an expensive, custom PCB or may damage the substrate.

Accordingly in one embodiment of the invention, the copper track 29 is located on the other side of the substrate 15 and is operatively coupled to the Hall Effect current sensor 14. For this PCB design to be functional, the PCB substrate should be magnetically transparent such as a reinforced fiberglass substrate. This design of the PCB enables a larger track dimension to be accommodated on the substrate without modification to the substrate, thereby enabling full-range current measurements to be obtained. Use of a Hall Effect current sensor also reduces board space.

The embodiments of the invention in which an exclusive property or privilege is claimed are defined as follows:

1. Wireless apparatus for switching at least one energy load with an AC power source comprising:
a load-interface device having
a relay between the at least one energy load and the AC power source,
a controller operatively connected to the relay;
a toggle and a wireless transceiver connected to the controller; and
a remote wireless transceiver unit in communication with the wireless transceiver,
wherein the controller operates the relay for changing the state of the electrical continuity between the at least one energy load and the AC power source
(i) in response to a change in state of the toggle regardless of a state signaled through wireless signals received from the remote wireless transmitting unit, and
(ii) in response to a change in the state signaled through the wireless signals received by the transceiver from the wireless transceiver unit regardless of the state of the toggle.

2. The wireless apparatus of claim 1, wherein the controller, the load-interface device are in a controlled receptacle and the toggle is located on the controlled receptacle.

3. The wireless apparatus of claim 1, wherein the controlled receptacle is adapted to receive at least a plug of the at least one energy load.

4. The wireless apparatus of claim 1, wherein the controller is operatively connected to an energy monitoring device

5. The wireless apparatus of claim 4, wherein the energy monitoring device comprises a current measuring unit and a power measuring unit.

6. The wireless apparatus of claim 5, wherein the energy monitoring device monitors the at least one energy load and communicates with controller for operating the relay.

7. The wireless apparatus of claim 5, wherein the current measuring unit includes a Hall Effect current sensor.

8. The wireless apparatus of claim 7, wherein the energy monitoring device further comprises a printed circuit board wherein:
the Hall Effect current sensor is an integrated circuit mounted on one side of the printed circuit board; and
the printed circuit board has at least one copper track on an other side thereof, the at least one copper track carrying current to be measured and operatively positioned with respect to the Hall Effect current sensor.

9. The wireless apparatus of claim 8, wherein the printed circuit board comprises a reinforced fiberglass substrate which is magnetically transparent.

10. The wireless apparatus of claim 4, wherein the energy monitoring device is operatively connected to the controller for automatically changing the state of the relay on the basis of predetermined set of variables.

11. The wireless apparatus of claim 10, wherein the predetermined set of variables includes at least one of energy usage patterns and cost of energy.

12. The wireless apparatus of claim 10, wherein the predetermined set of variables includes at least time of day.

13. The wireless apparatus of claim 4, wherein the energy monitoring device is operatively connected to the controller to operate the relay when power consumed by the at least one energy load exceeds a predetermined limit.

14. The wireless apparatus of claim 4, wherein the energy monitoring device is adapted to communicate with the controller to automatically turn on and off the at least one energy load when temperature around the at least one energy load drops below set values within a preset time of day.

15. The wireless apparatus of claim 4, wherein the energy monitoring device further comprises a display for displaying the power consumed by the at least one energy load and costs associated with usage of the at least one energy load.

16. The wireless apparatus of claim 4, wherein the at least one energy load is a car block heater and the predetermined variables are time of day and temperature.

17. The wireless apparatus of claim 4, wherein the at least one energy load is a lamp and the predetermined variable is time of day.

18. The wireless apparatus of claim 1, wherein the toggle is a pushbutton switch or a paddle switch or a rocker switch.

19. The wireless apparatus of claim 1, wherein the remote wireless transmitting unit is a mobile wireless device such a laptop, a personal digital assistant (PDA), or a cell phone; or a wall mounted wireless device; or a personal computer (PC).

20. The wireless apparatus of claim 2, wherein the controlled receptacle further comprises a bypass outlet and the at least one energy load plugged into the bypass outlet is connected to the AC power source without an intermediate switching apparatus.

21. The wireless apparatus of claim 2, wherein the controller is connected to the relay through a relay driver such as a transistor driven opto coupler.

22. The wireless apparatus of claim 4, wherein the controlled receptacle houses the energy monitoring device.

23. A method of controlling at least one energy load comprising:
maintaining a log of power consumed by the at least one energy load over a set period of time to arrive at an average power consumed by the at least one energy load;
measuring the power consumed by the at least one energy load at a given instant to arrive at an instant power;
comparing the instant power with the average power; and
determining that the at least one energy load is outside operating limits when the instant power exceeds the average power by a predetermined tolerance.

24. The method of claim 23 further comprising
connecting the at least one energy load to a load-interface device having a relay between the at least one energy load and an AC power source, a controller operatively connected to the relay and a wireless transceiver connected to the controller, and
when having determined that the at least one energy load is outside operating limits, then
operating the relay for changing the state of the electrical continuity between the at least one energy load and the AC power source.

25. A method of installing a wireless apparatus for changing status of at least one energy load connected to an AC power source comprising:
providing a controlled receptacle comprising a load-interface device, the load-interface device having
a relay between the at least one energy load and the AC power source,
a controller operatively connected to the relay;
a toggle and a wireless transceiver connected to the controller; and
a remote wireless transceiver unit in communication with the wireless transceiver; and
replacing a conventional receptacle for receiving a plug of the at least one energy load or an electrical switch controlling the at least one energy load with the controlled receptacle.

26. The method of claim 25 further comprising:
replacing the conventional receptacle for receiving a plug of the at least one energy load with the controlled receptacle; and
replacing the conventional electrical switch controlling the at least one energy load with an electrical outlet adapted to receive the remote wireless transceiver unit, the remote wireless transceiver unit comprising an interface for activating the transceiver unit.
